(19) United States
(12) Patent Application Publication
(10) Pub. No.: US 2013/0026655 A1
(43) Pub. Date: Jan. 31, 2013

(54) CHIP PACKAGE STRUCTURE AND METHOD OF MANUFACTURING THE SAME

(71) Applicants: Baik-woo LEE, Gwangmyeon-si (KR); Hyung-jae Shin, Seongnam-si (KR)

(72) Inventors: Baik-woo LEE, Gwangmyeon-si (KR); Hyung-jae Shin, Seongnam-si (KR)

(73) Assignee: Samsung Electronics Co., Ltd., Suwon-si (KR)

(21) Appl. No.: 13/438,103

(22) Filed: Apr. 3, 2012

(30) Foreign Application Priority Data
Jul. 25, 2011 (KR) 10-2011-0073772

(51) Int. Cl. H01L 23/52; H01L 21/50

(52) U.S. Cl. 257/777; 438/109; 257/E23.141; 257/E21.499

(57) ABSTRACT

A chip package structure includes a substrate in which a plurality of grooves are formed, an adhesive layer disposed on the substrate, and a plurality of chips attached to the adhesive layer. In addition, a method of fabricating the chip package structure includes forming a plurality of grooves in the substrate, dispensing a die attach material on a plurality of chip attaching regions between the plurality of grooves, and attaching a plurality of chips respectively on the plurality of chip attaching regions.

### CROSS-REFERENCE TO RELATED APPLICATION

This application claims priority from Korean Patent Application No. 10-2011-0073772, filed on Jul. 25, 2011, in the Korean Intellectual Property Office, the disclosure of which is incorporated herein in its entirety by reference.

### BACKGROUND

1. Field

The present disclosure relates to chip package structures and methods of manufacturing chip package structures, and more particularly, to chip package structures in which a groove is formed in a substrate in order to reduce a gap between chips, and methods of manufacturing the chip package structures.

2. Description of the Related Art

An image sensor chip is a chip capable of converting an input optical image into an electric signal, and an ultrasonic transducer chip is a chip capable of converting an ultrasonic signal into an electric signal. Recently, research into obtaining a full field image of a large size by using the above chips has been conducted. In order to obtain a full field image of large size, a chip of large size which may observe a large area has been necessary. However, as the size of the chip increases, processing yield of the chip is greatly degraded. Thus, it is not effective that the full field image is obtained by using one chip of a large size. Therefore, research into obtaining the full field image by using small sized chips that are arranged in a two-dimensional array has been performed recently.

### SUMMARY

Additional aspects will be set forth in part in the description which follows and, in part, will be apparent from the description, or may be learned by practice of the presented embodiments.

According to an aspect of an exemplary embodiment, a chip package structure includes: a substrate including a plurality of grooves formed therein; an adhesive layer disposed on the substrate; and a plurality of chips attached to the adhesive layer, wherein the plurality of grooves respectively surround each of the plurality of chips.

At least one first groove of the plurality of grooves crosses at least one second groove of the plurality of grooves.

The plurality of grooves may be connected to each other.

A width of each of the plurality of grooves may be equal to or greater than a gap between two adjacent chips.

The plurality of chips may be electrically connected to the substrate by a wire bonding or a flip-chip bonding.

The adhesive layer may include a die attach material.

The die attach material may include an epoxy group resin, an acryl group resin, a polyimide group resin, a silicon group resin, a mixture of the resins, or a solder material.

The plurality of chips may be arranged on the substrate in a two-dimensional (2D) array of m×n (m and n are natural numbers equal to 1 or greater).

Each of the plurality of chips may include a stack of two or more chips.

The plurality of chips may include semiconductor chips, sensor chips, or microelectromechanical systems (MEMS) chips.

The substrate may include an organic substrate, a silicon substrate, or a ceramic substrate.

According to another aspect of an exemplary embodiment, a method of fabricating a chip package structure is provided, the method including: forming a plurality of grooves in a substrate; dispensing a die attach material on a plurality of chip attaching regions between the plurality of grooves; and attaching a plurality of chips respectively onto the plurality of chip attaching regions.

The plurality of grooves may be formed by a photolithography process, a laser process, or an etching process.

In the forming of the plurality of grooves, a plurality of through-holes may be formed in a second substrate layer and the second substrate layer may be stacked on a first substrate layer.

The plurality of grooves may be respectively formed around each of the plurality of chips.

At least one first groove of the plurality of grooves may cross at least one second groove of the plurality of grooves.

The plurality of grooves may be connected to each other.

A width of each of the plurality grooves may be equal to or greater than a gap between two adjacent chips.

The method may further include curing the die attach material by applying heat and pressure to the die attach material.

According to another aspect of an exemplary embodiment, a method of fabricating a chip package structure is provided, the method including: forming a plurality of grooves in a substrate; forming at least one bump on a surface in each of a plurality of chips; attaching the plurality of chips onto the substrate; and injecting an underfill material between the substrate and the plurality of chips.

The plurality of grooves may be respectively formed around the plurality of chips.

At least one first groove of the plurality of grooves may cross at least one second groove of the plurality of grooves.

The plurality of grooves may be connected to each other.

A width of each of the plurality grooves may be equal to or greater than a gap between two adjacent chips.

### BRIEF DESCRIPTION OF THE DRAWINGS

These and/or other exemplary aspects and advantages will become apparent and more readily appreciated from the following description of exemplary embodiments, taken in conjunction with the accompanying drawings in which:

FIG. 1 is a schematic cross-sectional view of a chip package structure according to an exemplary embodiment;

FIGS. 2A and 2B are schematic plan views showing examples of a groove formed on a substrate of the chip package structure of FIG. 1;

FIG. 3 is a schematic cross-sectional view of a chip package structure according to a comparative example;

FIG. 4 is a schematic cross-sectional view of a chip package structure according to another exemplary embodiment;

FIG. 5 is a schematic cross-sectional view of a chip package structure according to another exemplary embodiment;

FIGS. 6A through 6E are schematic cross-sectional views illustrating a method of manufacturing a chip package structure according to an exemplary embodiment; and

FIGS. 7A through 7D are schematic cross-sectional views illustrating a method of manufacturing a chip package structure according to another exemplary embodiment.

### DETAILED DESCRIPTION

Various example embodiments will now be described more fully with reference to the accompanying drawings in which some example embodiments are shown.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In the drawings, the thicknesses of layers and regions are exaggerated for clarity. Like reference numerals in the drawings denote like elements.

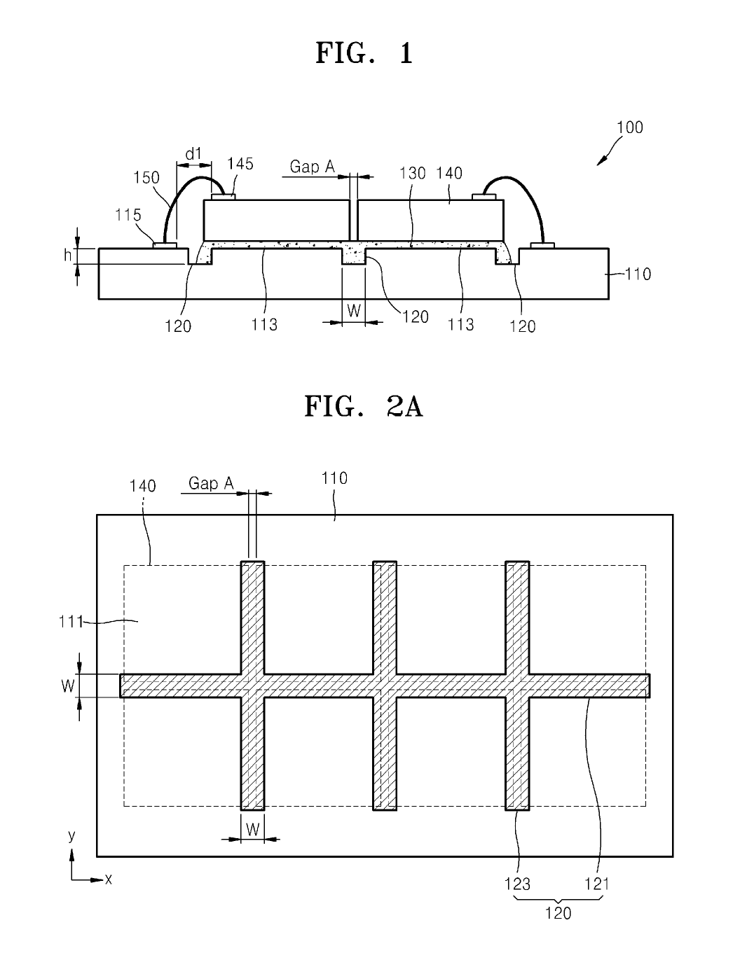

FIG. 1 is a schematic cross-sectional view of a chip package structure 100 according to an exemplary embodiment.

Referring to FIG. 1, the chip package structure 100 includes a substrate 110 on which a plurality of grooves 120 are formed, an adhesive layer 130 formed on the substrate 110, and a plurality of chips 140 disposed on the adhesive layer 130.

The substrate 110 may be an organic substrate, a silicon substrate, or a ceramic substrate. In addition, the substrate 110 may be a direct bonded copper (DBC) substrate or a printed circuit board (PCB). The plurality of grooves 120 may be formed in the substrate 110. At least one of the plurality of grooves 120 may be formed to cross other grooves. In addition, the plurality of grooves 120 may be connected to each other to form one groove.

The plurality of chips 140 may be arranged as a two-dimensional (2D) array of m×n (here, m and n are natural numbers equal to 1 or greater) on the substrate 110. The plurality of chips 140 may include semiconductor chips, sensor chips, or microelectromechanical systems (MEMS) chips; however, embodiments are not limited thereto. Here, the semiconductor chip may be an electronic chip based on a semiconductor wafer formed of silicon, and the sensor chip may be a photo-sensor chip, an image sensor chip, or a touch sensor chip. In addition, the MEMS chip may include a mechanical device formed by a micro-process. The MEMS chip may include an ultrasonic transducer, for example, a capacitive micromachined ultrasonic transducer (CMUT) or a piezoelectric micromachined ultrasonic transducer (PMUT).

The adhesive layer 130 is formed on the substrate 110, and the plurality of chips 140 are disposed on the adhesive layer 130. That is, the plurality of chips 140 may be attached to the substrate 110 via the adhesive layer 130. The adhesive layer 130 may be formed of a die attach material, and the die attach material may be an adhesive that may attach a chip (or die) onto the substrate. The die attach material may include, for example, an epoxy group resin, an acryl group resin, a polyimide group resin, a silicon group resin, or a mixture thereof. In addition, the die attach material may include a solder.

The plurality of grooves 120 may be formed in the substrate 110. The plurality of grooves 120 may be respectively formed around the plurality of chips 140. In more detail, the grooves 120 may be formed under four side surfaces of each of the chips 140 so as to surround each of the chips 140. That is, the grooves 120 may be formed between adjacent chips 140. In addition, the grooves 120 may be formed between the chip 140 and a second bonding pad 115 on the substrate 110.

Each of the grooves 120 may have a rectangular cross-section; however, the embodiments are not limited thereto. For example, each of the grooves 120 may have a regular square cross-section, a square cross-section, an inverse triangle cross-section, or a semi-circular cross-section. A width W of each of the grooves 120 may be equal to or greater than a gap A between the two adjacent chips 140. The grooves 120 may be formed to have a depth h that is sufficient to hold the die attach material so as not to flow between the chips 140 and not to contaminate the bonding pad 115.

Remaining excess die attach material of the adhesive layer 130 after attaching the chips 140 onto the substrate may be held in the grooves 120. That is, the grooves 120 may prevent the remaining die attach material from forming one or more fillets around the chips 140 due to possible overflow of the remaining die attach material under the chips 140. Therefore, in the chip package structure 100 of the present embodiment, the gap A between the plurality of chips 140 disposed on the substrate 110 may be reduced, and the plurality of chips 140 may be integrated in a small area. On the other hand, if the chip package structure 100 of the present embodiment includes ultrasonic transducer chips as the chips 140, gaps between the ultrasonic transducer chips that are arranged in a 2D array may be reduced. Therefore, continuous images may be obtained by using the chip package structure 100, and distortion of the image may be prevented. In addition, a full field image may be obtained by using ultrasonic transducer chips that are arranged in the 2D array in the chip package structure 100.

At least one first bonding pad 145 may be further disposed on each of the plurality of chips 140, and at least one second bonding pad 115 may be further disposed on the substrate 110. In addition, the bonding pads 145 and 115 may be electrically connected to each other by wires 150. The wire 150 may be formed of metal, for example, gold (Au), copper (Cu), aluminum (Al), or an alloy of metals.

The grooves 120 may be formed between the chips 140 and the second bonding pad 115 on the substrate 110. The die attach material after attaching the chips 140 onto the substrate 110 may be held in the grooves 120. Therefore, the chip package structure 100 may prevent the die attach material from contaminating the second bonding pad 115 on the substrate 110. In addition, a distance d1 between the first bonding pad 145 on the chip 140 and the second bonding pad 115 on the substrate 110 may be reduced, and thus the wire 150 may be short, too. When the wire 150 is short, reliability of the electric connection through the wire bonding may be improved.

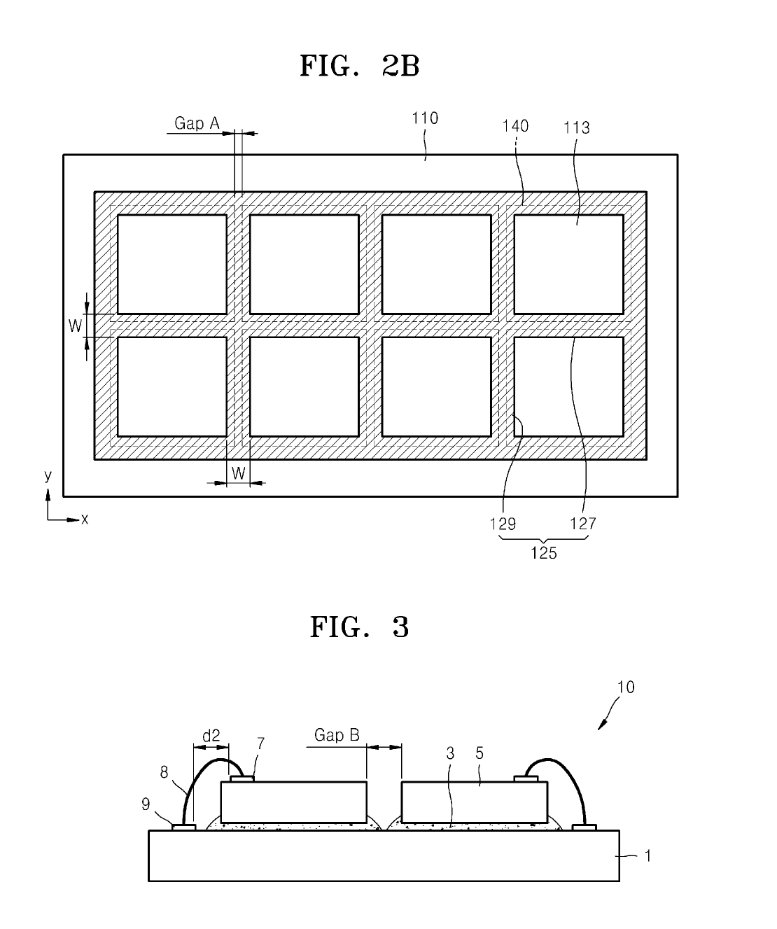

FIGS. 2A and 2B are schematic plan views showing examples of the grooves 120 formed in the substrate of the chip package structure 100 of FIG. 1. The plurality of chips 140 are arranged in the 2D array of 2×4; however, embodiments are not limited thereto. The chips 140 are denoted by dotted lines for the convenience of description.

Referring to FIG. 2A, the plurality of grooves 120 may be formed in the substrate 110 between the plurality of chips 140. That is, the grooves 120 may be formed between adjacent chips 140. A width W of each of the grooves 120 may be equal to or greater than the gap A between the chips 140. The grooves 120 may include a first groove 121 formed in an x-axis direction and a plurality of second grooves 123 formed in a y-axis direction. The plurality of second grooves 123 may be arranged in parallel with each other. In addition, the first groove 121 and the plurality of second grooves 123 may be formed to cross each other, and may cross each other at right angles. Also, the first groove 121 and the second grooves 123 may form a plurality of chip attaching regions 111, to which the chips 140 may be attached, on the substrate 110. An area of each of the chip attaching region 111 may be equal to or smaller than an area of each of the chips 140.

Referring to FIG. 2B, a plurality of grooves 125 may be formed on the substrate 110 so as to surround the plurality of chips 140, respectively. That is, the grooves 125 may be formed under four sides in each of the plurality of chips 140. A width W of the each groove 125 may be equal to or greater than the gap A between the chips 140. The grooves 125 may include a plurality of first grooves 127 formed in an x-axis direction and a plurality of second grooves 129 formed in a y-axis direction. The plurality of first grooves 127 may be arranged in parallel with each other, and the plurality of the second grooves 129 may be arranged in parallel with each other, too. The first grooves 127 and the second grooves 129 may be formed to cross each other, and may cross each other at right angles. In addition, the first grooves 127 and the second grooves 129 may form a plurality of chip attaching regions 113, to which the chips 140 may be attached, on the substrate 110. An area of each of the chip attaching regions 113 may be equal to or smaller than the area of each of the chips 140.

FIG. 3 is a schematic cross-sectional view of a chip package structure 10 according to a comparative example.

Referring to FIG. 3, the chip package structure 10 according to the comparative example includes a substrate 1, an adhesive layer 3 disposed on the substrate 1, and a plurality of chips 5 attached on the adhesive layer 3. A chip attaching material is dispensed on the substrate 1, and then, the chips 5 are attached onto the chip attaching material. When heat and pressure are applied to the chips 5 and the chip attaching material, the chip attaching material flows under the chips 5 and forms a fillet. That is, the adhesive layer 3 of the chip package structure 10 of the comparative example inevitably includes the fillet formed around the chips 5. The fillet makes it difficult to reduce a gap B between the plurality of chips 5. Therefore, in the chip package structure 10 according to the comparative example, it is difficult to integrate the plurality of chips 5.

If the gap B between the chips 5 is reduced regardless of the fillet formed around the chips 5, the chips 5 may be attached to the substrate 1 in a state in which side surfaces of the chips 5 are inclined with respect to the substrate 1, not perpendicular to the substrate 1 due to the fillet. In addition, the chip attaching material remaining after attaching the chips 5 to the substrate 1 overflows between the chips 5, and thus, performances of the chips 5 may be degraded. In addition, the fillet interferes with the reducing of a distance d2 between a bonding pad 7 on the chip 5 and a bonding pad 9 on the substrate 1. Therefore, a wire 8 used in a wire bonding process becomes longer according to the chip package structure 10 of the comparative example, and reliability of the electric connection between the chips 5 and the substrate 1 via the wire bonding may be degraded.

On the other hand, according to the chip package structure 100 shown in FIG. 1, remaining die attach material is held in the grooves 120 formed in the substrate 110 so as to prevent the fillet from forming around the chips 140. Therefore, in the chip package structure 100, the gap A between the plurality of chips 140 disposed on the substrate 110 may be reduced, and the plurality of the chips 140 may be integrated in a smaller area than that of the comparative example.

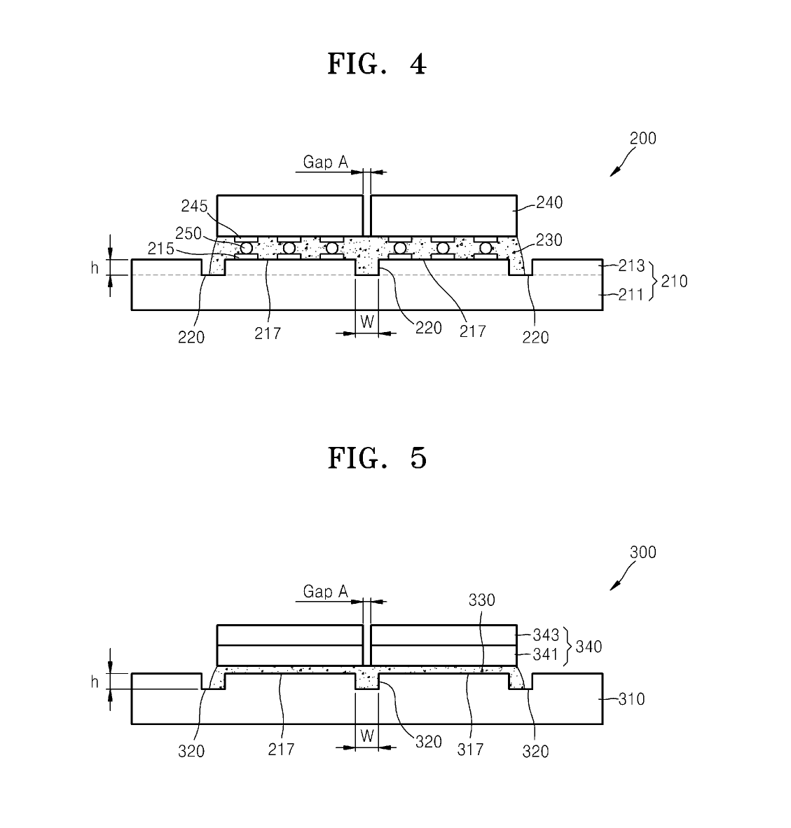

FIG. 4 is a schematic cross-sectional view of a chip package structure 200 according to another exemplary embodiment.

Referring to FIG. 4, the chip package structure 200 includes a substrate 210 on which a plurality of grooves 220 are formed, an adhesive layer 230 disposed on the substrate 210, and a plurality of chips 240 disposed on the adhesive layer 230. In addition, the plurality of chips 240 may be flip-chip bonded to the substrate 210.

The substrate 210 may be an organic substrate, a silicon substrate, or a ceramic substrate. In addition, the substrate 210 may be a direct bonded copper (DBC) substrate or a printed circuit board (PCB). Also, the substrate 210 includes a first substrate 211 and a second substrate 213 disposed on the first substrate 211. The first and second substrate 211 and 213 may be laminated to each other. The plurality of grooves 220 may be formed by bonding the second substrate 213 on the first substrate 211 after forming a plurality of through-holes in the second substrate 213. Among the plurality of grooves 220, at least one groove may be formed to cross the other grooves. In addition, the plurality of grooves 220 may be connected to each other.

The plurality of chips 240 may be arranged in a two-dimensional (2D) array of m×n (m and n are natural numbers equal to 1 or greater) on the substrate 210. The plurality of chips 240 may include semiconductor chips, sensor chips, or MEMS chips; however, the present invention is not limited thereto. Here, the semiconductor chip may be an electronic chip based on a semiconductor wafer formed of silicon, and the sensor chip may be a photosensor chip, an image sensor chip, or a touch sensor chip. In addition, the MEMS chip includes a mechanical device formed by a fine processing. For example, the MEMS chip may include an ultrasonic transducer, and in more detail, the MEMS chip may include a CMUT or a PMUT.

The plurality of chips 240 may be flip-chip bonded to the substrate 210. At least one first bonding pad 215 may be disposed on the substrate 210, and at least one second bonding pad 245 may be disposed on a lower surface of the chip 240. In addition, one or more bumps 250 may be disposed between the first and second bonding pads 215 and 245. The bumps 250 may be formed of tin, lead, silver, bismuth, antimony, copper, or an alloy thereof.

The adhesive layer 230 may be disposed between the substrate 210 and the chips 240. In addition, the adhesive layer 230 may surround the bumps 250, and fill between the substrate 210 and the chips 240. That is, when the substrate 210 and the chips 240 are flip-chip bonded to each other, the adhesive layer 230 may be formed of an underfill material. The underfill material may be, for example, an epoxy group resin, an acryl group resin, a polyimide group resin, a silicon group resin, or a mixture thereof. Here, the adhesive layer 230 may reinforce bonding between the substrate 210 and the chips 240, and may buff stress that is applied to the bumps 250 due to a difference between thermal expansion rates of the substrate 210 and the chips 240. In addition, the adhesive layer 230 may absorb external shocks, reduce tension applied to the bump 250, and increase lifespan of the chip package structure 200.

The plurality of grooves 220 may be formed respectively around the plurality of chips 240. In more detail, the grooves 220 may be formed between adjacent chips 240. That is, the grooves 220 may be formed under edges of the two adjacent chips 240, which face each other. In addition, the grooves 220 may be formed under four side surfaces of the chips 240 so as to surround each of the chips 240.

The grooves 220 may have rectangular cross-sections as shown in FIG. 4; however, the present invention is not limited thereto. For example, the grooves 220 may have perfect square, square, inverted triangle, or semicircular cross-sections. A width W of each of the grooves 220 may be equal to or greater than the gap A between adjacent chips 240. The grooves 220 may be formed to a depth h so that the underfill material do not overflow between the chips 240 and may fill between the bumps 250.

The underfill material forming the adhesive layer 230 is injected through the grooves 220 so as to fill spaces between the plurality of bumps 250. That is, the adhesive layer 230 may prevent air from being trapped between the substrate 210 and the chips 240. In addition, remaining excess underfill material is held in the grooves 220, and thus, potential overflow of the underfill material under the chips 240 and forming of the fillet around the chips 240 may be prevented. Therefore, according to the chip package structure 200, the gap A between the plurality of chips 240 disposed on the substrate 210 may be reduced, and the plurality of chips 240 may be integrated on the small area.

FIG. 5 is a schematic cross-sectional view of a chip package structure 300 according to another exemplary embodiment. Differences between the chip package structure 300 and the chip package structures 100 and 200 described above will be described as follows.

Referring to FIG. 5, the chip package structure 300 includes a substrate 310 on which a plurality of grooves 320 are formed, an adhesive layer 330 disposed on the substrate 310, and a plurality of chips 340 disposed on the adhesive layer 330.

Each of the plurality of chips 340 may include two or more stacked chips. That is, a first chip 341 is attached on the adhesive layer 330 and a second chip 343 may be attached on the first chip 341. The first chip 341 may be an application-specific integrated circuit (ASIC) and the second chip 343 may be one of semiconductor chip, sensor chip, and MEMS chip. For example, the first chip 341 may be the ASIC and the second chip 343 may be an ultrasonic transducer chip, that is, CMUT.

The chip package structure 300 costs less than a case in which a silicon interposer is used, and there is no worry about an electric coupling between the silicon interposer and the substrate. In addition, the first and second chips 341 and 343, for example, the CMUT and the ASIC are bonded in chip-to-chip way, and thus, parasitic components may be reduced. In addition, according to the chip package structure 300, a die attach material remaining after bonding the chips 340 onto the substrate 310 may be held in the grooves 320. That is, the fillet formed around the chips 340 due to the overflow of the remaining die attach material under the chips 340 may be prevented. Therefore, in the chip package structure 300 of the present embodiment, the gap A between the plurality of chips 340 disposed on the substrate 310 may be reduced, and thus, the plurality of chips 340 may be integrated in a small area.

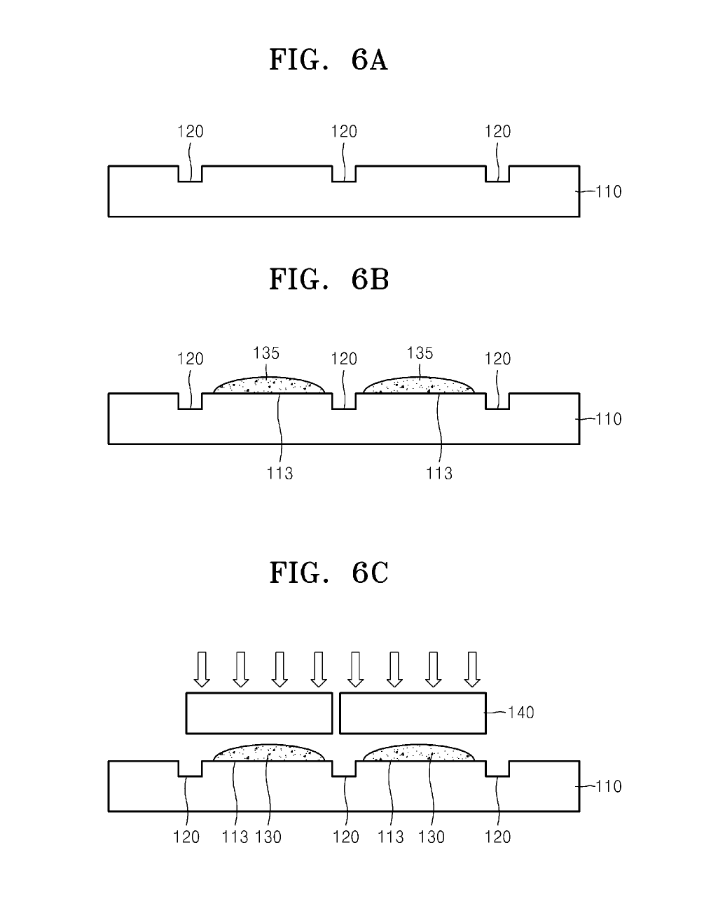

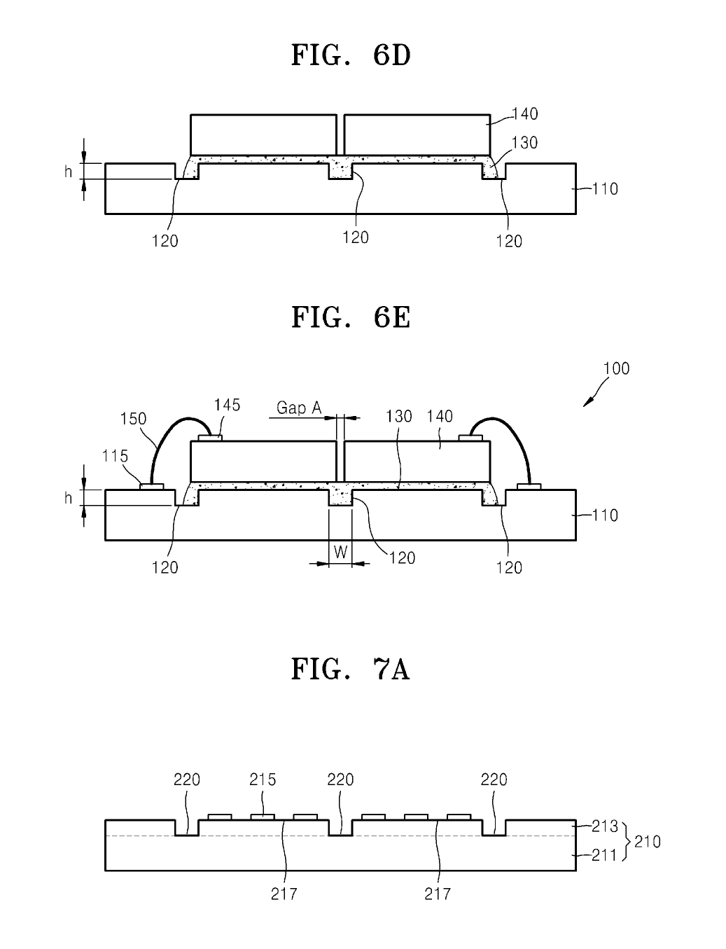

FIGS. 6A through 6E are schematic cross-sectional views illustrating processes of fabricating the chip package structure 100 according to an exemplary embodiment.

Referring to FIG. 6A, the substrate 110 is prepared, and the plurality of grooves 120 may be formed in the substrate 110. The substrate 110 may be an organic substrate, a silicon substrate, or a ceramic substrate. In addition, the substrate 110 may be a DBC substrate or a PCB. The grooves 120 may be formed in the substrate 110 by a photolithography process, an etching process, or a laser process. For example, the grooves 120 may be formed by a laser routing process or a plasma etching process. At least one groove 120 among the plurality of grooves 120 may be formed to cross the other grooves 120. In addition, the plurality of grooves 120 may be connected to each other as one groove.

Referring to FIG. 6B, a die attach material 135 may be dispensed between the plurality of grooves 120. That is, the die attach material 135 may be applied on the plurality of chip attaching regions 113 disposed between the grooves 120. The chip attaching regions are arranged in a 2D array of m×n (m and n are natural numbers equal to 1 or greater). The die attach material 135 may be an adhesive that may attach the chips (or dies) onto the substrate 110. The die attach material 135 may include an epoxy group resin, an acryl group resin, a polyimide group resin, a silicon group resin, or a mixture thereof. In addition, the die attach material 135 may include, for example, a solder.

Referring to FIG. 6C, the plurality of chips 140 may be respectively attached onto the die attach material 135 that is applied on the substrate 110. That is, the plurality of chips 140 may be arranged in a 2D array form having m×n arrangement (m and n are natural numbers equal to 1 or greater) on the chip attaching regions 113 on the substrate 110. Here, the grooves 120 may be formed respectively around the plurality of chips 140 that are attached to the substrate 110.

Referring to FIG. 6D, at least one of heat and pressure may be applied to the chips 140 and the die attach material 135 to form the adhesive layer 130. That is, the adhesive layer 130 may be formed by curing the die attach material 135.

Referring to FIG. 6E, the substrate 110 and the chips 140 are electrically connected to each other. At least one first bonding pad 145 is formed on the chips 140, and at least one second bonding pad 115 is formed on the substrate 110. Then, the first and second bonding pads 145 and 115 may be connected to each other by a wire 150. The wire 150 may be formed of metal, for example, gold, copper, aluminum, or an alloy thereof.

In addition, the grooves 120 may be formed under four side surfaces of the chips 140 so as to surround each of the chips 140. That is, the grooves 120 may be formed between adjacent chips 140. In addition, the grooves 120 may be formed between the chips 140 and the second bonding pad 115 on the substrate 110. According to the method of fabricating the chip package structure 100 of the present embodiment, the gaps A between the chips 140 are reduced so as to integrate the plurality of chips 140 in a small area. On the other hand, the width w of each of the grooves 120 may be equal to or greater than the gap A between the adjacent chips 140. The grooves 120 may be formed to a predetermined depth h so that the remaining die attach material does not overflow between the chips 140 and does not contaminate the second bonding pad 115.

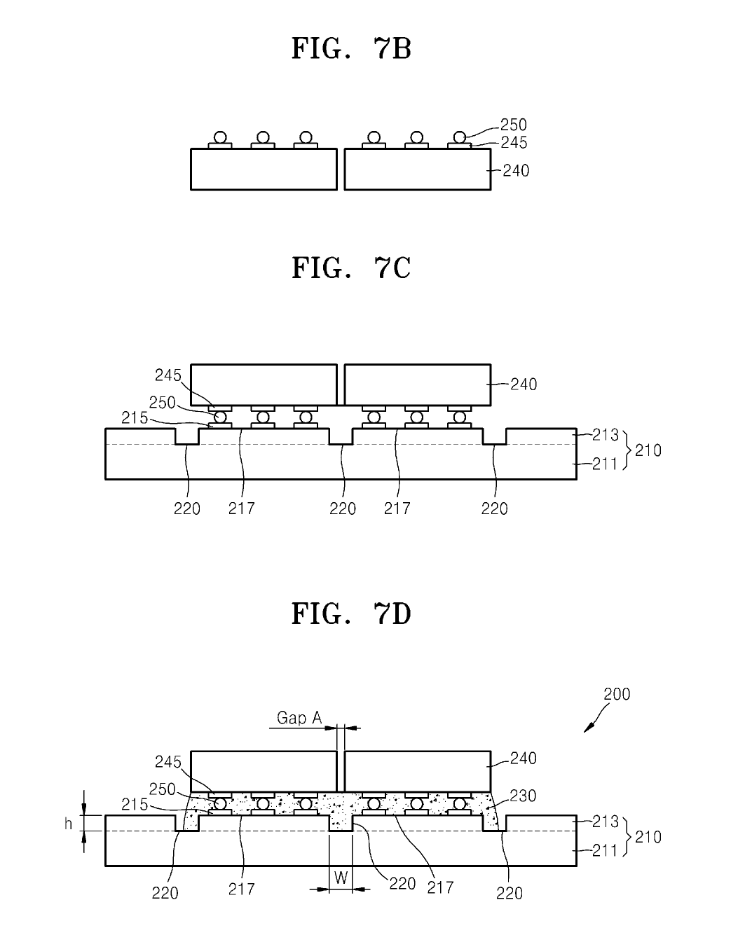

FIGS. 7A through 7D are schematic cross-sectional views illustrating processes of fabricating the chip package structure 200 according to another exemplary embodiment.

Referring to FIG. 7A, the first substrate 211 and the second substrate 213 are prepared. In addition, a plurality of penetrating holes are formed in the second substrate 213, and the second substrate 213 is stacked on the first substrate 211. In this way, the plurality of grooves 220 may be formed in the substrate 210. Among the plurality of grooves 220, at least one groove may cross the other grooves 220. In addition, the plurality of grooves 220 may be connected to each other to form one groove.

The plurality of grooves 220 may form a plurality of chip attaching regions 217 on the substrate 210, and the chip attaching regions 217 may be arranged in a 2D array of m×n (m and n are natural numbers equal to 1 or greater). The first and second substrates 211 and 213 may be organic substrates, silicon substrate, or ceramic substrate. In addition, the first and second substrates 211 and 213 may be DBC substrates or PCB. The penetrating holes formed in the second substrate 213 may be formed by a photolithography process, an etching process, or a laser process. For example, the penetrating holes may be formed by a laser routing or a plasma etching process. In addition, at least one first bonding pad 215 may be formed on the chip attaching region 217 on the second substrate 213.

Referring to FIG. 7B, at least one second bonding pad 245 may be formed on a lower surface of the chip 240, and at least one bump 250 may be formed on the second bonding pad 245.

Referring to FIG. 7C, the chips 240 may be attached onto the substrate 210. For example, the chips 240 may be flip-chip bonded to the substrate 210. That is, the bump 250 disposed on the lower surface of the chip 240 may be bonded to the first bonding pad 215 disposed on the substrate 210. The plurality of chips 240 are arranged on the chip attaching regions 217 of the substrate 210 in a 2D array of m×n (m and n are natural numbers equal to 1 or greater). The grooves 220 may be formed around the plurality of chips 240 that are attached to the substrate 210. In more detail, the grooves 220 may be formed between the adjacent chips 240. That is, the grooves 220 may be formed under edges of the adjacent chips 240, which face each other. In addition, the grooves 220 may be formed under the four side surfaces of the chips 240 so as to surround each of the chips 240. In addition, heat and pressure may be applied to the chips 240 and the bumps 250 so that the bumps 250 are melted to bond the chips 240 to the substrate 210.

Referring to FIG. 7D, the underfill material may be injected between the substrate 210 and the chips 240. In addition, the underfill material injected between the substrate 210 and the chips 240 is heated to form the adhesive layer 230. The underfill material may include, for example, an epoxy group resin, an acryl group resin, a polyimide group resin, a silicon group resin, or a mixture thereof. The adhesive layer 230 may reinforce a bonding between the substrate 210 and the chips 240, and may buff the stress applied to the bump 250 due to a difference between thermal expansion rates of the substrate 210 and the chips 240. In addition, the adhesive layer 230 may absorb the external shock, reduce tension applied to the bump 250, and may extend the lifespan of the chip package structure 200.

In addition, the width W of each of the grooves 220 may be equal to or greater than the gap A between the adjacent chips 240. The grooves 220 may be formed to a predetermined depth h so that the underfill material may fill the gap between the substrate 210 and the chips 240 without overflowing between the chips 240. Therefore, according to the method of fabricating the chip package structure 200 of the present embodiment, the gaps A between the chips 240 may be reduced so that the plurality of chips 240 may be integrated on a small area.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A chip package structure comprising:
a substrate comprising a plurality of grooves formed therein;
an adhesive layer disposed on the substrate; and
a plurality of chips attached to the adhesive layer,
wherein the plurality of grooves respectively surround each of the plurality of chips.

2. The chip package structure of claim 1, wherein at least one first groove of the plurality of grooves crosses at least one second groove of the plurality of grooves.

3. The chip package structure of claim 1, wherein the plurality of grooves are connected to each other.

4. The chip package structure of claim 1, wherein a width of each of the plurality of grooves is equal to or greater than a gap between two adjacent chips.

5. The chip package structure of claim 1, further comprising a wire bonding or a flip-chip bonding electrically connecting each of the plurality of chips to the substrate.

6. The chip package structure of claim 1, wherein the adhesive layer comprises a die attach material.

7. The chip package structure of claim 6, wherein the die attach material comprises one of an epoxy group resin, an acryl group resin, a polyimide group resin, a silicon group resin, a mixture of the resins, and a solder material.

8. The chip package structure of claim 1, wherein the plurality of chips are arranged on the substrate in a two-dimensional array of m×n, wherein m and n are natural numbers equal to 1 or greater.

9. The chip package structure of claim 1, wherein each of the plurality of chips comprises a stack of two or more chips.

10. The chip package structure of claim 1, wherein the plurality of chips comprise at least one of semiconductor chips, sensor chips, and microelectromechanical systems chips.

11. The chip package structure of claim 1, wherein the substrate comprises one of an organic substrate, a silicon substrate, and a ceramic substrate.

12. The chip package structure of claim 1, wherein each of the plurality of chips is attached to one of a plurality of chip attaching regions on the surface of the substrate via the adhesive layer.

13. A method of fabricating a chip package structure, the method comprising:
forming a plurality of grooves in a substrate;
dispensing a die attach material on a plurality of chip attaching regions between the plurality of grooves; and
attaching a plurality of chips respectively onto the plurality of chip attaching regions.

14. The method of claim 13, wherein the forming the plurality of grooves comprises forming the plurality of grooves by one of a photolithography process, a laser process, and an etching process.

15. The method of claim 13, wherein the forming of the plurality of grooves comprises forming a plurality of through-holes in a second substrate layer and stacking the second substrate layer on a first substrate layer.

16. The method of claim 13, wherein the plurality of grooves respectively surround each of the plurality of chips.

17. The method of claim 13, wherein at least one first groove of the plurality of grooves crosses at least one second groove of the plurality of grooves.

18. The method of claim 13, wherein the plurality of grooves are connected to each other.

19. The method of claim 13, wherein a width of each of the plurality grooves is equal to or greater than a gap between two adjacent chips.

20. The method of claim 13, further comprising curing the die attach material by applying heat and pressure to the die attach material.

21. A method of fabricating a chip package structure, the method comprising:
forming a plurality of grooves in a substrate;
forming at least one bump on a surface in each of a plurality of chips;
attaching the plurality of chips onto the substrate; and
injecting an underfill material between the substrate and the plurality of chips.

22. The method of claim 21, wherein the plurality of grooves respectively surround each of the plurality of chips.

23. The method of claim 21, wherein at least one first groove of the plurality of grooves crosses at least one second groove of the plurality of grooves.

24. The method of claim 21, wherein the plurality of grooves are connected to each other.

25. The method of claim 22, wherein a width of each of the plurality grooves is equal to or greater than a gap between two adjacent chips.
